(19) United States
(12) Patent Application Publication
(10) Pub. No.: US 2016/0013249 A1
(43) Pub. Date: Jan. 14, 2016

(54) ORGANIC LIGHT EMITTING DISPLAY PANEL

(71) Applicant: AU OPTRONICS CORP., Hsin-Chu (TW)

(72) Inventors: Yu-Ching WANG, Hsin-Chu (TW); Ching-Yan CHAO, Hsin-Chu (TW)

(21) Appl. No.: 14/511,276

(22) Filed: Oct. 10, 2014

(30) Foreign Application Priority Data
Jul. 10, 2014 (TW) 103123802

(51) Int. Cl. H01L 27/32

(52) U.S. Cl. CPC H01L 27/3211; H01L 27/322; H01L 51/5056

(57) ABSTRACT

An organic light emitting display panel includes an array substrate, at least one blue sub-pixel, at least one green sub-pixel, and at least one red sub-pixel. The blue sub-pixel, the green sub-pixel, and the red sub-pixel are disposed on the array substrate and are respectively configured for providing blue light, green light, and red light. The blue sub-pixel, the green sub-pixel, and the red sub-pixel together have a light emitting surface. The light emitting surface has a normal direction which is along a normal line of the light emitting surface, and has an oblique direction which forms an angle greater than 0 degree with the normal line. The red light has a red normal intensity RI1 along the normal direction, and a red oblique intensity RI2 along the oblique direction. When the angle is about 15 degrees, 1.12≧RI2/RI1≧1.

### RELATED APPLICATIONS

This application claims priority to Taiwan Application Serial Number 103123802, filed Jul. 10, 2014, which is herein incorporated by reference.

### BACKGROUND

1. Field of Invention

The present invention relates to an organic light emitting display panel, especially relates to a top emission organic light emitting display panel.

2. Description of Related Art

In general, an organic light emitting display panel includes blue sub-pixels, green sub-pixels, and red sub-pixels (RGB). The blue sub-pixels, the green sub-pixels, and the red sub-pixels respectively provide blue light, green light, and red light to generate color images of the organic light emitting display panel. For an organic light emitting display panel, due to micro-cavity effect, the wavelength of each RGB generally shows a blueshift at wide viewing angles, resulting in blue-green hue of white light at oblique observing direction. Therefore, many manufacturers in the industry are striving to solve the color cast problem of white color at wide viewing angle.

### SUMMARY

An aspect of the present invention is to provide an organic light emitting display panel includes an array substrate, at least one blue sub-pixel, at least one green sub-pixel, and at least one red sub-pixel. The blue sub-pixel is disposed on the array substrate and is configured for providing blue light. The green sub-pixel is disposed on the array substrate and is configured for providing green light. The red sub-pixel is disposed on the array substrate and is configured for providing red light. The blue sub-pixel, the green sub-pixel, and the red sub-pixel together have a light emitting surface. The light emitting surface has a normal direction along a normal line of the light emitting surface, and has an oblique direction which forms an angle greater than 0 degree with the normal line. The red light has a red normal intensity RI1 along the normal direction, and a red oblique intensity RI2 along the oblique direction. When the angle is about 15 degrees, 1.12≧RI2/RI1≧1.

### BRIEF DESCRIPTION OF THE DRAWINGS

FIG. 1 is a cross-sectional view of an organic light emitting display panel according to one embodiment of present invention;

FIG. 2 is an enlarged diagram of area P in FIG. 1;

FIG. 3 is a graph of simulated (RI2/RI1) value of the second thickness of the red sub-pixel of FIG. 2 vs. at different angles;

FIG. 4 is a graph of experimental (RI2/RI1) values, (GI2/GI1) values, and (BI2/BI1) values of a comparison example according to the present invention at different angles;

FIG. 5 is a graph of experimental (RI2/RI1) values, (GI2/GI1) values, and (BI2/BI1) values of an example according to the present invention at different angles;

FIG. 6 is a graph of experimental (RI2/RI1) values, (GI2/GI1) values, and (BI2/BI1) values of another example according to the present invention at different angles;

FIGS. 7, 8, and 9 are graphs of experimental (RI2/RI1) values, (GI2/GI1) values, and (BI2/BI1) values of another three examples according to the present invention at different angles;

FIG. 10 is a graph of the experimental data of the ratio of (RI2/RI1), the ΔCIEx of white light, and the yield according to different examples;

FIG. 11 is a cross-sectional view of an organic light emitting display panel according to another embodiment of present invention; and

FIGS. 12˜14 are graphs of experimental (RI2/RI1) values, (GI2/GI1) values, and (BI2/BI1) values of the organic light emitting display panel including the color filters according to the examples of the present invention at different angles.

### DETAILED DESCRIPTION

Reference will now be made in detail to the present embodiments of the invention, examples of which are illustrated in the accompanying drawings. Wherever possible, the same reference numbers are used in the drawings and the description to refer to the same or like parts.

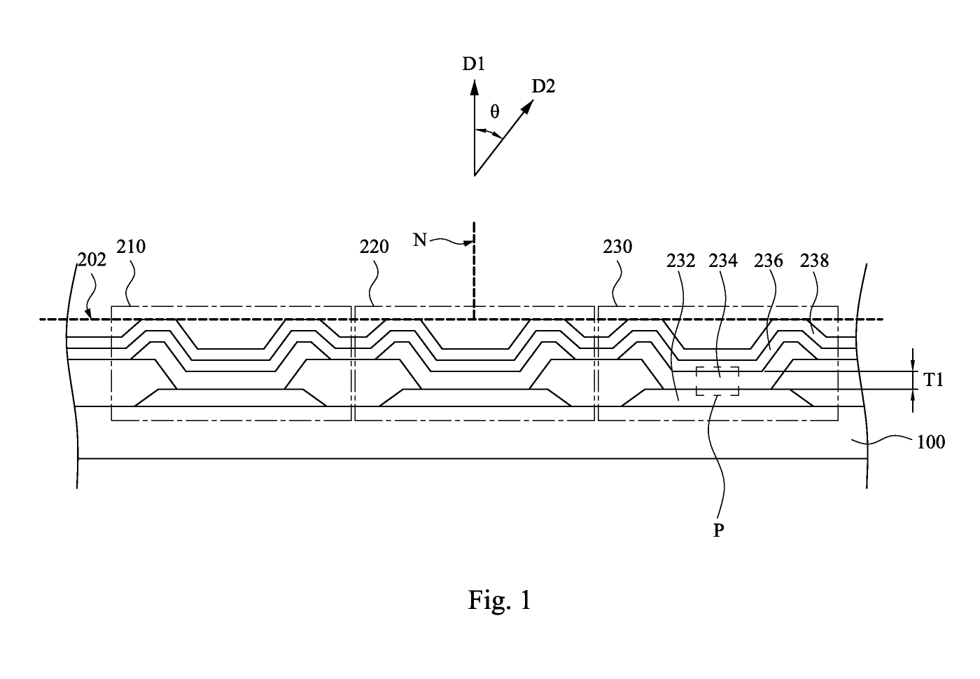

FIG. 1 is a cross-sectional view of an organic light emitting display panel according to one embodiment of present invention. The organic light emitting display panel includes an array substrate 100, at least one blue sub-pixel 210, at least one green sub-pixel 220, and at least one red sub-pixel 230. The blue sub-pixel 210 is disposed on the array substrate 100 and is configured for providing blue light. The green sub-pixel 220 is disposed on the array substrate 100 and is configured for providing green light. The red sub-pixel 230 is disposed on the array substrate 100 and is configured for providing red light. The blue sub-pixel 210, the green sub-pixel 220, and the red sub-pixel 230 together have a light emitting surface 202. The light emitting surface 202 has a normal direction D1 along a normal line N of the light emitting surface 202, and has an oblique direction D2 forming an angle θ greater than 0 degree with the normal line N. The red light has a red normal intensity (defined as RI1) along the normal direction D1, and has a red oblique intensity (defined as RI2) along the oblique direction D2. When the angle θ is about 15 degrees, 1.12≧RI2/RI1≧1.

It is noted that in this embodiment, the organic light emitting display panel mentioned above can be a top emission organic light emitting display panel. Since the blue sub-pixel 210, the green sub-pixel 220, and the red sub-pixel 230 are arranged side by side on the array substrate 110, the light emitting surface 202 can be parallel to the surface supporting the blue sub-pixel 210, the green sub-pixel 220, and the red sub-pixel 230. Moreover, the array substrate 100 can includes a plurality of switches (such as thin film transistors) arranged in an array manner. The switches are respectively configured for switching the blue sub-pixel 210, the green sub-pixel 220, and the red sub-pixel 230 on/off.

Briefly, the organic light emitting display panel of the present invention can improve the color cast problem of white color at wide viewing angle through adjust the ratio of the red oblique intensity RI2 to the red normal intensity RI1. For a general top emission organic light emitting display panel, when the angle is wider, not only all of the intensities of blue light, green light, and red light decay, but also the wavelength of the mixing white light is blue shifted. Therefore, for white light composition of the general organic light emitting display panel, the red light shows a larger blueshift than the blue light and the green light, such that the images becomes blue-green hue at wide viewing angles. However, in this embodiment, when the angle θ is about 15 degrees, 1.12≧RI2/RI1≧1. That is, the red oblique intensity RI2 is raised at the oblique direction D2, and the image shows slight blue-green hue, thereby the color cast problem of white color at wide viewing angle can be improved.

In one or more embodiments, the red sub-pixel 230 includes an anode layer 232, a cathode layer 236, and an organic layer 234. The organic layer 234 is disposed between the anode layer 232 and the cathode layer 236. The organic layer 234 has a first thickness T1, and 330 nm≧T1≧280 nm, where the first thickness T1 represents the vertical thickness of the organic layer 234. More specifically, the red light is emitted from the organic layer 234, is resonated between the anode layer 232 with strong reflection and the cathode layer 236 with partially reflection, and then transmits the cathode layer 236 to the light emitting surface 202. In other words, the organic layer 234 is a resonance cavity of the red light. Hence, the first thickness T1 can be regarded as the thickness of the resonance cavity along the normal direction D1. The red oblique intensity RI2 itself and the ratio of the red oblique intensity RI2 to the red normal intensity RI1 can be changed through adjusting the first thickness T1. Moreover, the red sub-pixel 230 can further include a cap layer 238 to cover the cathode layer 236.

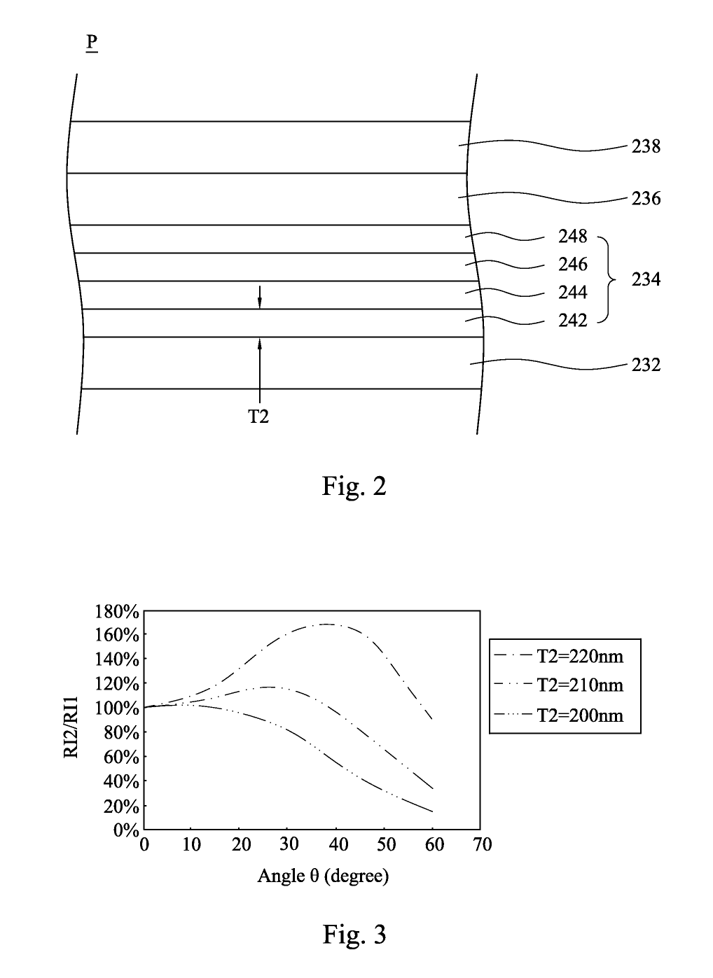

FIG. 2 is an enlarged diagram of area P in FIG. 1. As shown in FIG. 2, the organic layer 234 includes a hole injection layer (HIL) 242, a hole transport layer (HTL) 244, an emitting material layer (EML) 246, and an electron transport layer (ETL) 248. The hole injection layer 242 is disposed between the anode layer 232 and the cathode layer 236. The hole injection layer 242 has a second thickness T2, and 214 nm≧T2≧200 nm. The hole transport layer 244 is disposed between the hole injection layer 242 and the cathode layer 236. The emitting material layer 246 is disposed between the hole transport layer 244 and the cathode layer 236. The electron transport layer 248 is disposed between the emitting material layer 246 and the cathode layer 236. More specifically, the decay degree of the red oblique intensity RI2 as the angle θ increases can be changed through adjusting the second thickness T2.

FIG. 3 is a graph of simulated (RI2/RI1) value of the second thickness T2 of the red sub-pixel 230 of FIG. 2 at different angles θ. Reference is made to FIG. 3 and Table 1. As shown in FIG. 3, when the second thickness T2 was about 200 nm to 220 nm, and the angle θ was about 15 degrees, RI2/RI1≧1. Furthermore, when the second thickness T2 was about 210 nm and about 220 nm, and the angle θ was about 30 degrees, RI2/RI1≧1. Therefore, the decay degree of the red oblique intensity RI2 as the angle θ increases can be change through adjusting the second thickness T2.

TABLE 1
parameters of the red light with different second thicknesses T2

| The second thickness T2 | 200 nm | 210 nm | 220 nm |
|---|---|---|---|
| Yield | 37.3 | 28.1 | 16.2 |
| CIE 1931 x value | 0.6733 | 0.6895 | 0.6982 |
| CIE 1931 y value | 0.3251 | 0.3081 | 0.2975 |
| Red light maximum | 616 nm | 632 nm | 648 nm |
| intensity wavelength | | | |
| RI2/RI1 | 100% | 108% | 118% |
| (θ = 15 degrees) | | | |
| RI2/RI1 | 82% | 115% | 160% |
| (θ = 30 degrees) | | | |
| RI2/RI1 | 42% | 82% | 161% |
| (θ = 45 degrees) | | | |
| RI2/RI1 | 15% | 34% | 91% |
| (θ = 60 degrees) | | | |

The yield, the CIE (International Commission of Illumination) 1931 x value, the CIE 1931 y value, and the red light maximum intensity wavelength of Table 1 are the values along the normal direction D1. Moreover, according to Table 1, the CIE 1931 x value is about 0.67 to about 0.695, and the red light maximum intensity wavelength is about 616 nm to about 640 nm.

The following paragraphs provide detailed explanations with respect to how to improve the color cast problem of white color at wide viewing angle using the red sub-pixel 230. Reference is made to FIG. 1. In one or more embodiments, the green light has a green normal intensity (defined as GI1) along the normal direction D1, and has a green oblique intensity (defined as GI2) along the oblique direction D2. The blue light has a blue normal intensity (defined as BI1) along the normal direction D1, and has a blue oblique intensity (defined as BI2) along the oblique direction D2. When the angle θ is about 15 degrees to about 60 degrees,

65%≧(RI2/RI1)−(GI2/GI1)≧3%, and

75%≧(RI2/RI1)−(BI2/BI1)≧5%.

That is, along the oblique direction D2, further, the angle θ is about 15 degrees to about 60 degrees, the decay degree of the red light is slighter than those of the green light and the blue light. Even more, the red oblique intensity RI2 can be higher than the red normal intensity RI1. This way, the decay degree of the red oblique intensity RI2 is slighter than those of the green oblique intensity GI2 and the blue oblique intensity BI2 along the oblique direction D2. The fraction of the red light is enhanced to compensate the blue shift effect in the resonance cavity (microcavity), such that the blue-green hue along the oblique direction D2 can be improved. The blue light has a blue light maximum intensity wavelength along the normal direction D1, and the blue light maximum intensity wavelength is about 450 nm to about 476 nm. The green light has a green light maximum intensity wavelength along the normal direction D1, and the green light maximum intensity wavelength is about 512 nm to about 550 nm. The red light maximum intensity wavelength is about 616 nm to about 640 nm.

In greater detail, the properties of the red light provided by the red sub-pixel 230 of the present embodiment satisfies Table 2:

TABLE 2
The value ranges of (RI2/RI1)-(GI2/GI1) and
(RI2/RI1)-(BI2/BI1) at different angles θ

| The angle θ | (RI2/RI1)-(GI2/GI1) | (RI2/RI1)-(BI2/BI1) |
|---|---|---|
| about 15 | 25% ≧ (RI2/RI1)- | 25% ≧ (RI2/RI1)- |
| degrees | (GI2/GI1) ≧ 5% | (BI2/BI1) ≧ 8% |
| about 30 | 60% ≧ (RI2/RI1)- | 70% ≧ (RI2/RI1)- |
| degrees | (GI2/GI1) ≧ 10% | (BI2/BI1) ≧ 15% |
| about 45 | 65% ≧ (RI2/RI1)- | 75% ≧ (RI2/RI1)- |
| degrees | (GI2/GI1) ≧ 5% | (BI2/BI1) ≧ 10% |
| about 60 | 25% ≧ (RI2/RI1)- | 30% ≧ (RI2/RI1)- |
| degrees | (GI2/GI1) ≧ 3% | (BI2/BI1) ≧ 5% |

The value ranges of Table 2 can be obtained by, but not limited to, changing the second thickness T2 (see FIG. 2) of the hole injection layer 242 (see FIG. 2) of the organic layer 234 of the red sub-pixel 230.

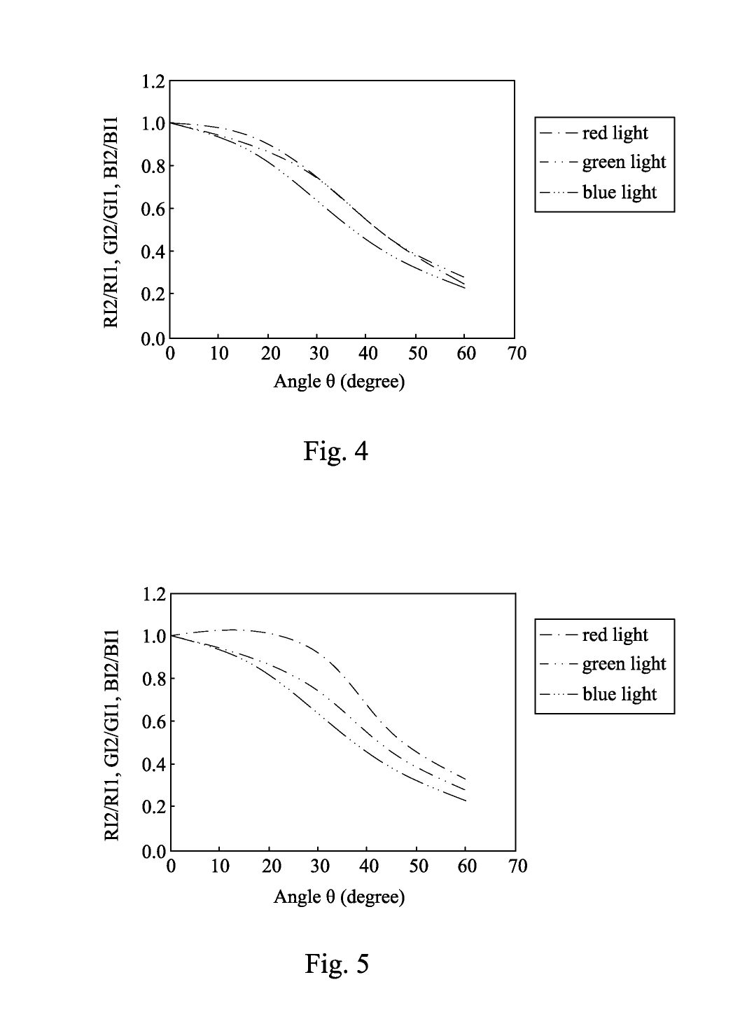

FIG. 4 is a graph of experimental (RI2/RI1) values, (GI2/GI1) values, and (BI2/BI1) values of a comparison example according to the present invention at different angles θ. Reference is made to FIG. 4 and Table 3. In this comparison example, the second thickness T2 (see FIG. 2) was 196 nm, and the red light maximum intensity wavelength was 614 nm. As shown in FIG. 4, when the angle θ increased, both of the blue light and the green light intensities decayed, and the decay degree of the red light was generally greater than those of the blue light and the green light. With this configuration, the CIE 1931 x value difference between 0 degree and 60 degrees of the white light was −0.052, and the CIE 1931 y value difference between 0 degree and 60 degrees of the white light was 0.006.

TABLE 3
The experimental data of the red light (RI2/RI1 =
0.95), the green light, and the blue light at different
angles θ according to the comparison example

| | | | | (RI2/RI1)- | (RI2/RI1)- |
|---|---|---|---|---|---|
| The angle θ | RI2/RI1 | GI2/GI1 | BI2/BI1 | (GI2/GI1) | (BI2/BI1) |
| 15 degrees | 95% | 91% | 89% | 4% | 6% |
| 30 degrees | 75% | 74% | 64% | 1% | 11% |
| 45 degrees | 46% | 46% | 38% | 0% | 8% |
| 60 degrees | 25% | 28% | 23% | −3% | 2% |

FIG. 5 is a graph of experimental (RI2/RI1) values, (GI2/GI1) values, and (BI2/BI1) values of an example according to the present invention at different angles θ. Reference is made to FIG. 5 and Table 4. In this example, the second thickness T2 (see FIG. 2) was 202 nm, and the red light maximum intensity wavelength was 616 nm. As shown in FIG. 5, when the angle θ increased, both of the blue light and the green light intensities decayed, and the decay degree of the red light was slighter than that of the blue light and the green light. In addition, when the angle θ was about 15 degrees, the red oblique intensity RI2 was higher than the red normal intensity RI1. With this configuration, the CIE 1931 x value difference between 0 degree and 60 degrees of the white light was only −0.036, and the CIE 1931 y value difference between 0 degree and 60 degrees of the white light was only 0.002. That is, to compare with the comparison example shown in FIG. 4 and Table 3, the organic light emitting display panel of this example had smaller CIE 1931 x and y value differences of the white light between the normal direction D1 and the oblique direction D2 (see FIG. 1). Therefore, it proves that 1.12≧RI2/RI1≧1 satisfied at about 15-degree angle θ improves the color cast problem of white color at wide viewing angle.

TABLE 4
The experimental data of the red light (RI2/RI1 =
1.02), the green light, and the blue light at different
angles θ according to the example of FIG. 5

| | | | | (RI2/RI1)- | (RI2/RI1)- |
|---|---|---|---|---|---|
| The angle θ | RI2/RI1 | GI2/GI1 | BI2/BI1 | (GI2/GI1) | (BI2/BI1) |
| 15 degrees | 102% | 91% | 89% | 11% | 13% |
| 30 degrees | 92% | 74% | 64% | 18% | 28% |
| 45 degrees | 55% | 46% | 38% | 9% | 17% |
| 60 degrees | 33% | 28% | 23% | 5% | 10% |

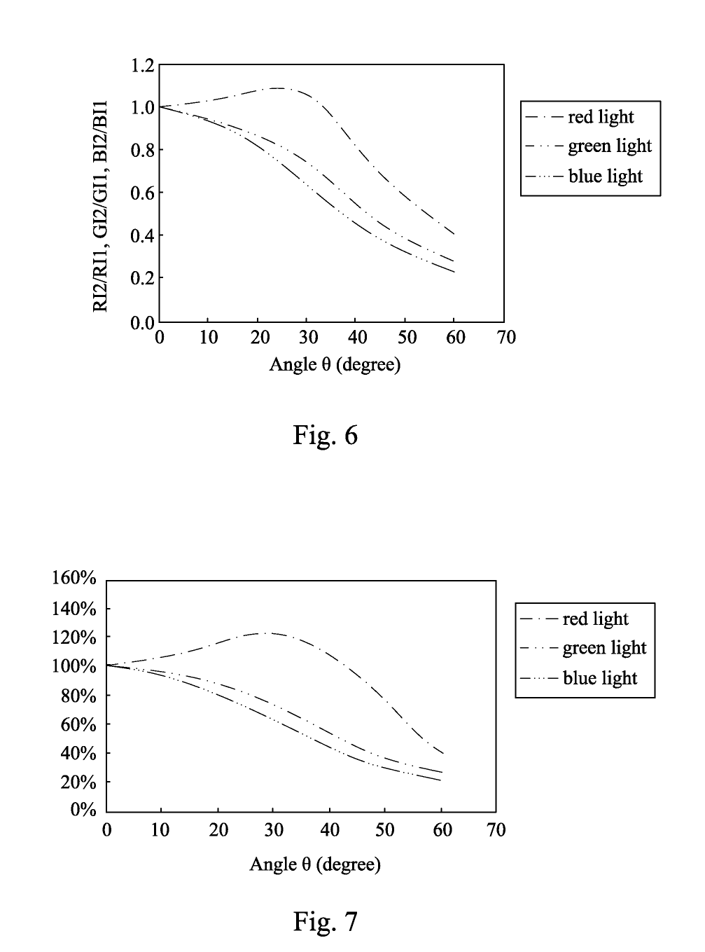

FIG. 6 is a graph of experimental (RI2/RI1) values, (GI2/GI1) values, and (BI2/BI1) values of another example according to the present invention at different angles θ. Reference is made to FIG. 6 and Table 5. In this example, the second thickness T2 (see FIG. 2) was 208 nm, and the red light maximum intensity wavelength was 624 nm. As shown in FIG. 6, when the angle θ increased, the decay degree of the red light was slighter than those of the blue light and the green light. In addition, when the angle θ was about 15 degrees and about 30 degrees, the red oblique intensity RI2 was higher than the red normal intensity RI1. With this configuration, the CIE 1931 x value difference between 0 degree and 60 degrees of the white light was only −0.021, and the CIE 1931 y value difference between 0 degree and 60 degrees of the white light was only 0.009. That is, to compare with the comparison example shown in FIG. 4 and Table 3, the organic light emitting display panel of this example had smaller CIE 1931 x and y value differences of the white light between the normal direction D1 and the oblique direction D2 (see FIG. 1). Therefore, it proves that 1.12≧RI2/RI1≧1 satisfied at about 15-degree angle θ improves the color cast problem of white color at wide viewing angle.

TABLE 5
The experimental data of the red light (RI2/RI1 =
1.05), the green light, and the blue light at different
angles θ according to the example of FIG. 6

| | | | | (RI2/RI1)- | (RI2/RI1)- |
|---|---|---|---|---|---|
| The angle θ | RI2/RI1 | GI2/GI1 | BI2/BI1 | (GI2/GI1) | (BI2/BI1) |
| 15 degrees | 105% | 91% | 89% | 14% | 16% |
| 30 degrees | 106% | 74% | 64% | 32% | 42% |
| 45 degrees | 69% | 46% | 38% | 23% | 31% |
| 60 degrees | 41% | 28% | 23% | 13% | 18% |

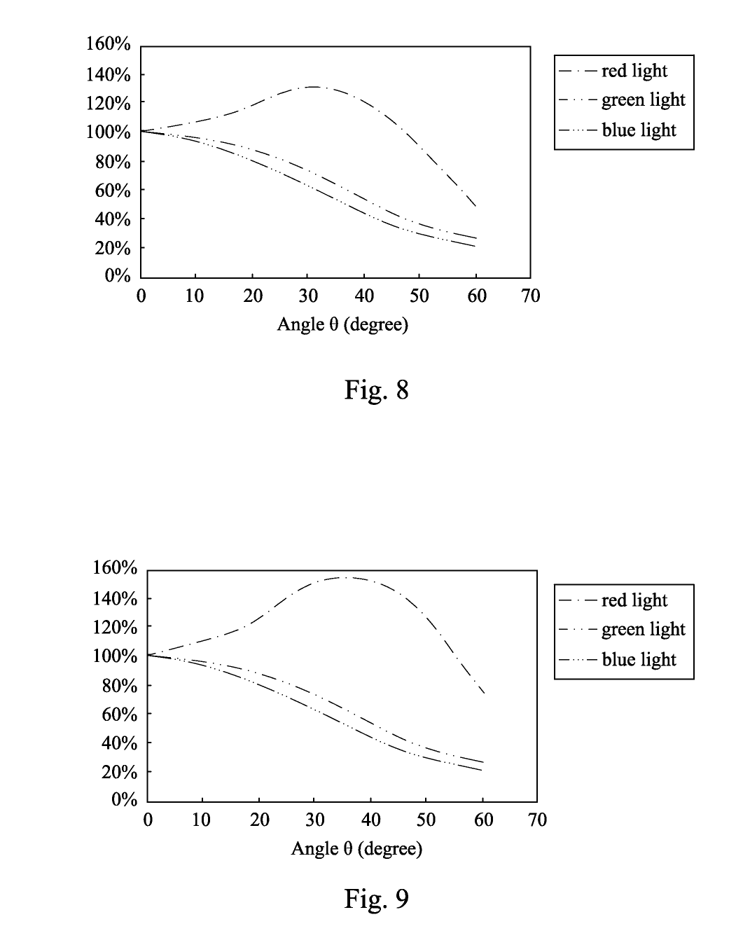

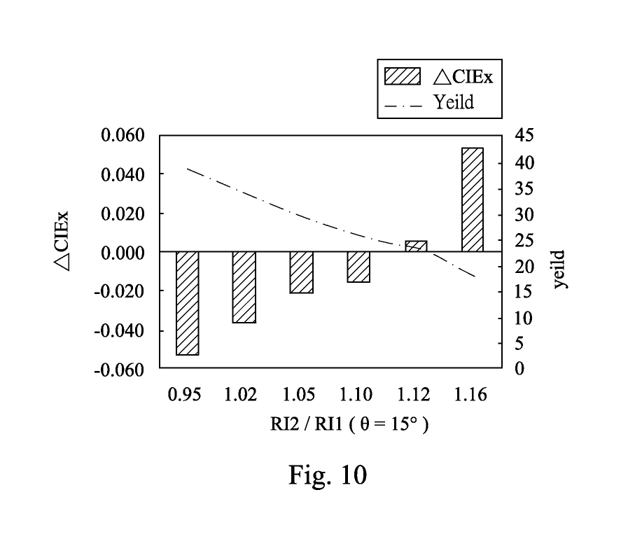

FIGS. 7, 8, and 9 are graphs of experimental (RI2/RI1) values, (GI2/GI1) values, and (BI2/BI1) values of another three examples according to the present invention at different angles θ. Reference is made to FIGS. 7, 8, 9 and Tables 6, 7, 8. In these examples, the second thickness T2 (see FIG. 2) were 212, 214, and 218 nm, and the red light maximum intensity wavelengths were 634, 638, and 644 nm. As shown in FIGS. 7, 8, and 9, when the angle θ increased, the decay degree of the red light was slighter than those of the blue light and the green light. In addition, when the angle θ was about 15 degrees and about 30 degrees, the red oblique intensity RI2 was higher than the red normal intensity RI1. With this configuration, the CIE 1931 x value differences between 0 degree and 60 degrees of the white light were only −0.015, 0.006, and 0.053, and the CIE 1931 y value differences between 0 degree and 60 degrees of the white light were only 0.002, 0.004, and 0.009. That is, with the second thickness T2=214 nm, the red light maximum intensity wavelength=638 nm, and RI2/RI1=1.12 at 15-degree angle θ (i.e., the example of FIG. 8 and Table 7), the organic light emitting display panel of this example had smaller CIE 1931 x and y value differences of the white light between the normal direction D1 and the oblique direction D2 (see FIG. 1). When RI2/RI1≧1.12, the red light oblique intensity RI2 was too high, as shown in Table 8 and FIG. 9. The mixed white light shifted to red hue at wide viewing angles, and the red light emitting efficiency (Yield) is continuously reduced, as shown in Table 9 and FIG. 10, thereby increasing energy consumption of the display panel. Therefore, a suitable range is claimed herein: when the angle θ is about 15 degrees, the condition of 1.12≧RI2/RI1≧1 is satisfied to effectively improve the color cast problem of white color at wide viewing angle. Also, the slower the red oblique intensity RI2 decays when the angle θ increases, the greater the color cast problem of white color at wide viewing angle improves, as shown in Table 10.

TABLE 6
The experimental data of the red light (RI2/RI1 =
1.1), the green light, and the blue light at
different angles θ according to another example

| | | | | (RI2/RI1)- | (RI2/RI1)- |
|---|---|---|---|---|---|
| The angle θ | RI2/RI1 | GI2/GI1 | BI2/BI1 | (GI2/GI1) | (BI2/BI1) |
| 15 degrees | 110% | 91% | 89% | 19% | 21% |
| 30 degrees | 123% | 74% | 64% | 49% | 59% |
| 45 degrees | 94% | 46% | 38% | 48% | 56% |
| 60 degrees | 41% | 28% | 23% | 13% | 18% |

TABLE 7
The experimental data of the red light (RI2/RI1 =
1.12), the green light, and the blue light
at different angles θ according to another example

| | | | | (RI2/RI1)- | (RI2/RI1)- |
|---|---|---|---|---|---|
| The angle θ | RI2/RI1 | GI2/GI1 | BI2/BI1 | (GI2/GI1) | (BI2/BI1) |
| 15 degrees | 112% | 91% | 89% | 21% | 23% |
| 30 degrees | 131% | 74% | 64% | 57% | 67% |
| 45 degrees | 108% | 46% | 38% | 62% | 70% |
| 60 degrees | 50% | 28% | 23% | 22% | 26% |

TABLE 8
The experimental data of the red light (RI2/RI1 =
1.16), the green light, and the blue light
at different angles θ according to another example

| | | | | (RI2/RI1)- | (RI2/RI1)- |
|---|---|---|---|---|---|
| The angle θ | RI2/RI1 | GI2/GI1 | BI2/BI1 | (GI2/GI1) | (BI2/BI1) |
| 15 degrees | 116% | 91% | 89% | 25% | 27% |
| 30 degrees | 150% | 74% | 64% | 76% | 86% |
| 45 degrees | 142% | 46% | 38% | 96% | 103% |
| 60 degrees | 74% | 28% | 23% | 46% | 51% |

TABLE 9
The experimental data of the ratio of (RI2/RI1),
the ΔCIEx of white light, and the yield according
to different examples mentioned above

| | | ΔCIEx (60 degrees-0 | |
|---|---|---|---|
| | RI2/RI1 as 15 degrees | degree) | Yield |
| Table 3 | 0.95 | −0.052 | 38.3 |
| Table 4 | 1.02 | −0.036 | 33.5 |
| Table 5 | 1.05 | −0.021 | 29.2 |
| Table 6 | 1.10 | −0.015 | 25.7 |
| Table 7 | 1.12 | 0.006 | 23.2 |
| Table 8 | 1.16 | 0.053 | 18.5 |

TABLE 10
The experimental data of CIE x, y of white light at the angle
θ = 60 degrees with different RI2/RI1

| | examples | | | | | |
|---|---|---|---|---|---|---|
| | RI2/RI1 = 0.95 | | RI2/RI1 = 1.02 | | RI2/RI1 = 1.05 | |
| | CIE | | | | | |
| | x | y | x | y | x | y |
| at angle | 0.3151 | 0.3189 | 0.3150 | 0.3206 | 0.3151 | 0.3208 |
| θ = 0° | | | | | | |
| at angle | 0.2633 | 0.3246 | 0.2789 | 0.3224 | 0.2942 | 0.3293 |
| θ = 60° | | | | | | |
| ΔCIE of | −0.052 | 0.006 | −0.036 | 0.002 | −0.021 | 0.009 |
| white light | | | | | | |
| (60°-0°) | | | | | | |
| | examples | | | | | |
| | RI2/RI1 = 1.1 | | RI2/RI1 = 1.12 | | RI2/RI1 = 1.16 | |
| | CIE | | | | | |
| | x | y | x | y | x | y |
| at angle | 0.3100 | 0.3210 | 0.3100 | 0.3204 | 0.3101 | 0.3202 |
| θ = 0° | | | | | | |
| at angle | 0.2951 | 0.3230 | 0.3156 | 0.3249 | 0.3628 | 0.3289 |
| θ = 60° | | | | | | |
| ΔCIE of | −0.015 | 0.002 | 0.006 | 0.004 | 0.053 | 0.009 |
| white light | | | | | | |
| (60°-0°) | | | | | | |

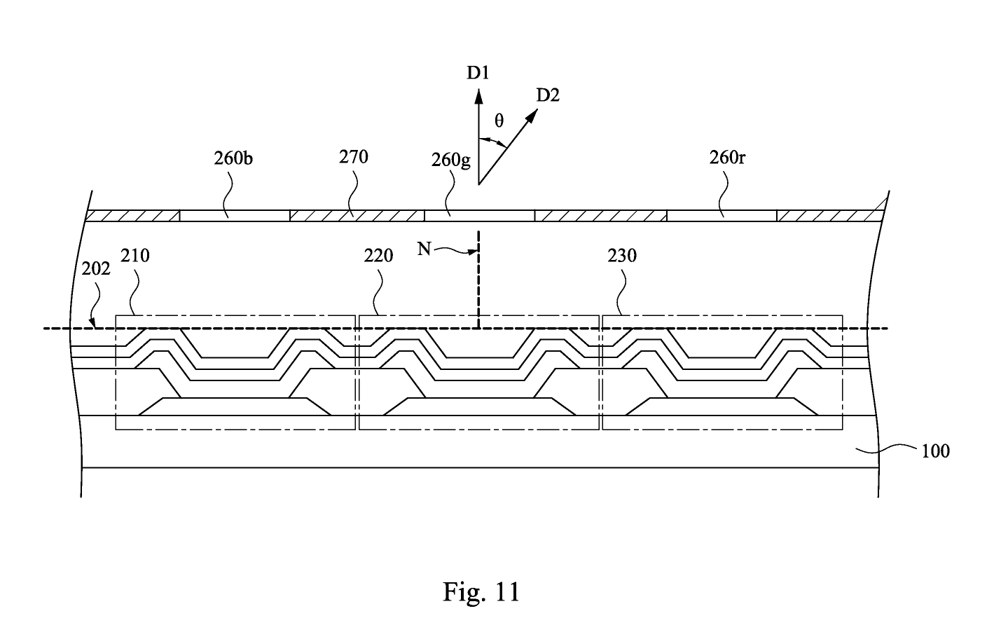

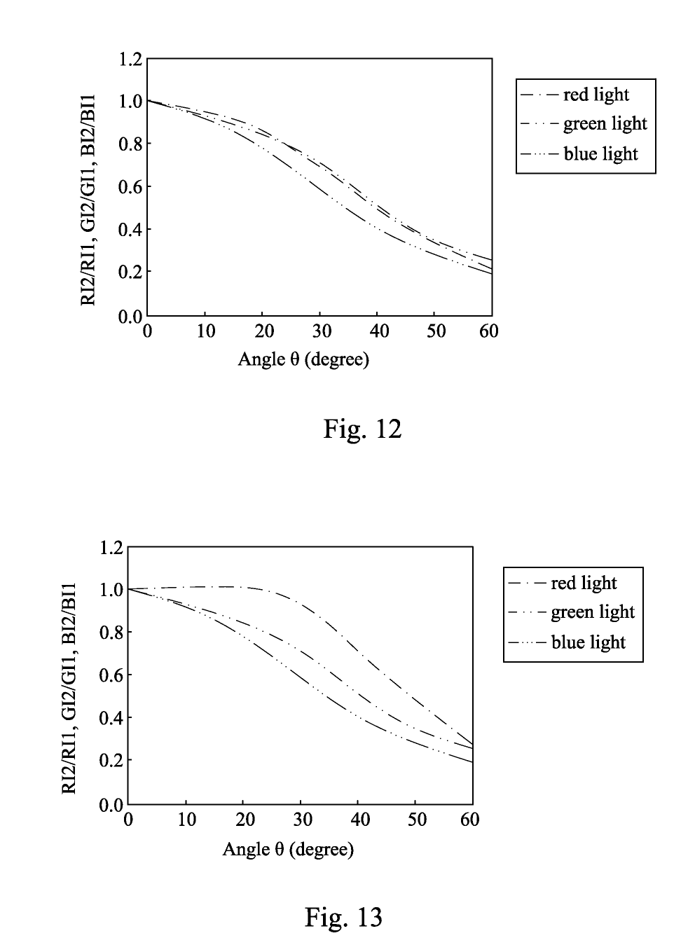

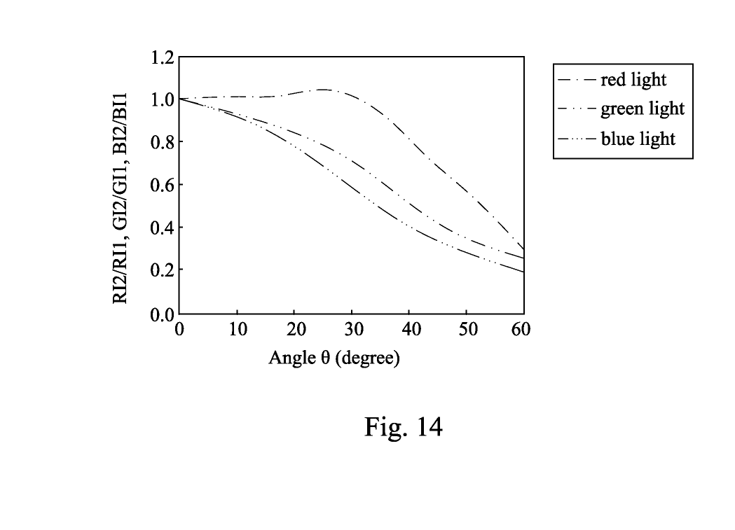

In one embodiment of the present invention, the organic light emitting display panel can include color filter configuration, as shown in FIG. 11, where color filters 260b, 260g, and 260r are respectively disposed corresponding to the blue sub-pixel 210, the green sub-pixel 220, and the red sub-pixel 230, and a black matrix 270 can be disposed among the color filters 260b, 260g, and 260r. FIGS. 12˜14 are graphs of experimental (RI2/RI1) values, (GI2/GI1) values, and (BI2/BI1) values of the organic light emitting display panel including the color filters 260b, 260g, and 260r according to the examples of the present invention at different angles θ, and the experimental (RI2/RI1) values, (GI2/GI1) values, and (BI2/BI1) values are shown in Table 11˜Table 13. In the comparison example (FIG. 12 and Table 11) and the examples (FIGS. 13, 14 and Tables 12, 13), the second thickness T2 (see FIG. 2) were 198, 212, 214 nm, and the red light maximum intensity wavelength were 615, 619, and 625 nm. As shown in FIGS. 13 and 14, when the angle θ increased, the decay degree of the red light was slighter than those of the blue light and the green light. In addition, when the angle θ was about 15 degrees, the red oblique intensity RI2 was higher than the red normal intensity RI1. With this configuration, the CIE 1931 x value differences between 0 degrees and 60 degrees of the white light were only −0.024 and −0.019, and the CIE 1931 y value differences between 0 degrees and 60 degrees of the white light were only −0.001, and 0.001. That is, to compare with the comparison example shown in FIG. 12 and Table 11 (whose CIE 1931 x value difference was −0.038 and CIE 1931 y value difference was −0.008), the organic light emitting display panel of these examples had smaller CIE 1931 x and y value differences of the white light between the normal direction D1 and the oblique direction D2 (see FIG. 11). Therefore, it proves that 1.12≧RI2/RI1≧1 satisfied at about 15-degree angle θ improves the color cast problem of white color at wide viewing angle. Also, the slower the red oblique intensity RI2 decays when the angle θ increases, the greater the color cast problem of white color at wide viewing angle improves. It further proves that the condition of 1.12≧RI2/RI1≧1 is also satisfied in the organic light emitting display panel including the color filter configuration, as shown in Table 14.

TABLE 11
The experimental data of the red light, the green light,
and the blue light of the organic light emitting display
panel including the color filter configuration at different
angles θ according to the comparison example of Fig. 12

| | | | | (RI2/RI1)- | (RI2/RI1)- |
|---|---|---|---|---|---|
| Angle θ | RI2/RI1 | GI2/GI1 | BI2/BI1 | (GI2/GI1) | (BI2/BI1) |
| 15 degrees | 94% | 92% | 88% | 2% | 6% |
| 30 degrees | 72% | 74% | 62% | −2% | 10% |
| 45 degrees | 43% | 43% | 34% | 0% | 9% |
| 60 degrees | 21% | 25% | 21% | −4% | 0% |

TABLE 12
The experimental data of the red light, the green light,
and the blue light of the organic light emitting display
panel including the color filter configuration at different
angles θ according to the example of FIG. 13

| | | | | (RI2/RI1)- | (RI2/RI1)- |
|---|---|---|---|---|---|
| Angle θ | RI2/RI1 | GI2/GI1 | BI2/BI1 | (GI2/GI1) | (BI2/BI1) |
| 15 degrees | 102% | 92% | 88% | 10% | 14% |
| 30 degrees | 95% | 74% | 62% | 21% | 33% |
| 45 degrees | 60% | 43% | 34% | 17% | 26% |
| 60 degrees | 28% | 25% | 21% | 3% | 7% |

TABLE 13
The experimental data of the red light, the green light,
and the blue light of the organic light emitting display
panel including the color filter configuration at different
angles θ according to the example of FIG. 14

| | | | | (RI2/RI1)- | (RI2/RI1)- |
|---|---|---|---|---|---|
| Angle θ | RI2/RI1 | GI2/GI1 | BI2/BI1 | (GI2/GI1) | (BI2/BI1) |
| 15 degrees | 103% | 92% | 88% | 11% | 15% |
| 30 degrees | 104% | 74% | 62% | 30% | 42% |
| 45 degrees | 70% | 43% | 34% | 27% | 36% |
| 60 degrees | 30% | 25% | 21% | 5% | 9% |

TABLE 14
The experimental data of CIE of white light at the angle θ = 60
degrees with different RI2/RI1

| | examples | | | | | |
|---|---|---|---|---|---|---|
| | RI2/RI1 = 0.94 | | RI2/RI1 = 1.02 | | RI2/RI1 = 1.03 | |
| | CIE | | | | | |
| | x | y | x | y | x | y |
| at angle | 0.3101 | 0.3200 | 0.3100 | 0.3202 | 0.3100 | 0.3202 |
| θ = 0° | | | | | | |
| at angle | 0.2716 | 0.3116 | 0.2863 | 0.3194 | 0.2911 | 0.3214 |
| θ = 60° | | | | | | |
| ΔCIE of | −0.038 | −0.008 | −0.024 | −0.001 | −0.019 | 0.001 |
| white light | | | | | | |
| (60°-0°) | | | | | | |

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. An organic light emitting display panel, comprising:
an array substrate;
at least one blue sub-pixel disposed on the array substrate and configured for providing blue light;
at least one green sub-pixel disposed on the array substrate and configured for providing green light; and
at least one red sub-pixel disposed on the array substrate and configured for providing red light, the blue sub-pixel, the green sub-pixel, and the red sub-pixel together having a light emitting surface, wherein the light emitting surface has a normal direction along a normal line of the light emitting surface and has an oblique direction forming an angle greater than 0 degree with the normal line, the red light has a red normal intensity RI1 along the normal direction, and a red oblique intensity RI2 along the oblique direction, when the angle is about 15 degrees, 1.12≧RI2/RI1≧1.

2. The organic light emitting display panel of claim 1, wherein the green light has a green normal intensity GI1 along the normal direction, and has a green oblique intensity GI2 along the oblique direction; the blue light has a blue normal intensity BI1 along the normal direction, and has a blue oblique intensity BI2 along the oblique direction; and when the angle is about 15 degrees to about 60 degrees,
65%≧(RI2/RI1)−(GI2/GI1)≧3%, and
75%≧(RI2/RI1)−(BI2/BI1)≧5%.

3. The organic light emitting display panel of claim 2, wherein when the angle is about 15 degrees,
25%≧(RI2/RI1)−(GI2/GI1)≧5%, and
25%≧(RI2/RI1)−(BI2/BI1)≧8%.

4. The organic light emitting display panel of claim 2, wherein when the angle is about 30 degrees,
60%≧(RI2/RI1)−(GI2/GI1)≧10%, and
70%≧(RI2/RI1)−(BI2/BI1)≧15%.

5. The organic light emitting display panel of claim 2, wherein when the angle is about 45 degrees,
65%≧(RI2/RI1)−(GI2/GI1)≧5%, and
75%≧(RI2/RI1)−(BI2/BI1)≧10%.

6. The organic light emitting display panel of claim 2, wherein when the angle is about 60 degrees,
25%≧(RI2/RI1)−(GI2/GI1)≧3%, and
30%≧(RI2/RI1)−(BI2/BI1)≧5%.

7. The organic light emitting display panel of claim 1, wherein the red light has a CIE 1931 x value along the normal direction and a red light maximum intensity wavelength along the normal direction, wherein the CIE 1931 x value is about 0.67 to 0.695, and the red light maximum intensity wavelength is about 616 to 640 nm.

8. The organic light emitting display panel of claim 1, wherein the red sub-pixel comprises:
an anode layer;
a cathode layer; and
an organic layer disposed between the anode layer and the cathode layer, wherein the organic layer has a first thickness T1, and 330 nm≧T1≧280 nm.

9. The organic light emitting display panel of claim 8, wherein the organic layer comprises:
a hole injection layer disposed between the anode layer and the cathode layer, wherein the hole injection layer has a second thickness T2, and 214 nm≧T2≧200 nm;
a hole transport layer disposed between the hole injection layer and the cathode layer;
an emitting material layer disposed between the hole transport layer and the cathode layer; and
an electron transport layer disposed between the emitting material layer and the cathode layer.

10. The organic light emitting display panel of claim 1, further comprising a plurality of color filters respectively disposed corresponding to the blue sub-pixel, the green sub-pixel, and the red sub-pixel.

11. The organic light emitting display panel of claim 1, wherein the blue light has a blue light maximum intensity wavelength along the normal direction, and the blue light maximum intensity wavelength is about 450 nm to about 476 nm; and the green light has a green light maximum intensity wavelength along the normal direction, and the green light maximum intensity wavelength is about 512 nm to about 550 nm.
